(19) United States
(12) Patent Application Publication
(10) Pub. No.: US 2006/0258033 A1
(43) Pub. Date: Nov. 16, 2006

(54) Active matrix substrate and method for fabricating the same

(75) Inventors: Kuo-Hsing Cheng, Taipei City (TW); Chao-Hsien Wu, Hsinchu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/254,002

(22) Filed: Oct. 19, 2005

(30) Foreign Application Priority Data
May 13, 2005 (TW) 94115530

(51) Int. Cl. H01L 21/00; H01L 33/00

(52) U.S. Cl. 438/30; 257/88

(57) ABSTRACT

An active matrix substrate and method for fabricating the same. The active matrix substrate, employed in a flat panel display (FPD), comprises a substrate having an active region and a pad region, a thin film transistor (TFT) disposed within the active region, a data pad and a gate pad, wherein the TFT includes a gate electrode, a semiconductor layer, a source electrode, and a drain electrode. Specifically, the data pad and the gate pad, made of the same material and formed by the same process, are located within the pad region coplanarly. Furthermore, the gate pad is electrically connected to the gate electrode, and the data pad is electrically connected to the source electrode.

### BACKGROUND

The present invention relates to an active matrix substrate and a method for fabricating the same and, more particularly, to an active matrix substrate with high aperture ratio and fabrication method thereof.

Liquid crystal displays (LCDs) are widely used due to advantages of reduced power consumption and thickness, lighter weight, and lower driving voltage. LCDs utilize charges in an arrangement of liquid crystal molecules when additional electric power is applied, whereby photoelectric effects are generated.

With increasing resolutions of LCDs, it has become important to increase the aperture ratio of each pixel for improved performance. To increase the aperture ratio, an ultra-high aperture ratio (UHA) pixel structure with a polymer layer with low dielectric constant and high transparency has been developed.

FIG. 1 is a top view of a conventional LCD 10 with UHA pixel structure, and FIG. 2 is sectional diagrams of FIG. 1 along lines A-A′, B-B′, and C-C′. The LCD 10 comprises a transparent substrate 12, defined as a thin film transistor region 2 and a pad region 1.

A first conductive layer is formed on the substrate 12 and patterned by a first photolithography process to form gate electrodes 20 and gate lines 120. Next, a gate insulating layer 13 is formed on the substrate 12, and a patterned semiconductor layer 14 is formed on the gate insulating layer 13 by a second photolithography process. Next, a second conductive layer is formed on the substrate 12 and patterned by third photolithography process to form source electrodes 22, drain electrodes 24, and data line 130.

Next, a passivation layer 30 and a polymer layer 40 are sequentially formed on the substrate 12 and patterned by a fourth photolithography process to form a gate line contact hole 50, a drain contact hole 51, and a data line contact hole 52 therethrough. Finally, a transparent electrode is formed on the polymer layer 40, and patterned by a fifth photolithography process to form contact regions 60 and a pixel electrode 61, wherein the contact regions 60 electrically connect to gate pads 56 and data pads 57 respectively.

In the package process of the conventional LCD with UHA pixel structure, an adhesive is formed directly on the polymer layer. Due to inferior adhesion thereto, the liquid crystal may leak via the gap between the adhesive and the polymer layer 40.

Further, an anisotropic conductive adhesive layer 70 is formed on the contact regions 60, before mounting circuit boards thereon. Since the gate line and data line contact holes 50 and 52 pass through the passivation layer 30 and polymer layer 40, the anisotropic conductive adhesive layer 70 may close off the top of the contact holes 50 and 52 before filling the contact holes 50 and 52, resulting in voids 72, referring to FIG. 3, disadvantageously increasing resistance of interconnect and may even contributing to electromigration-based failure of interconnect.

To overcome the drawbacks described, another LCD with high aperture ratio has also been disclosed, referring to FIG. 4. In the process for fabricating the LCD 100, after forming the passivation layer 30 and the polymer layer 40, the polymer layer 40 within the pad region 1 is removed by additional photolithography, thereby facilitating adhesive formation directly on the passivation layer 30 and reducing the depth of contact holes 150 and 152.

The aforementioned fabrication method, however, requires at least six photolithography steps, which increases costs and lowers throughput and yield. Further, the gate pads 56 and data pads 57 are made of different materials and formed in different processes, and the gate pad and data pad contact holes 150 and 152 having different depths are formed by the same process. That is, the narrow process window of the conventional LCD increases the difficulty of manufacturing.

Therefore, on the premise that the process window is unlimited and the process complexity is not increased, a novel LCD with UAH pixel structure is called for.

### SUMMARY

It is an objection of the present invention to provide an active matrix substrate with UAH pixel structure, employed in a flat panel display. An exemplary embodiment of an active matrix substrate comprises a substrate having an active region and a pad region. A thin film transistor disposed within the active region includes a gate electrode, a semiconductor layer, a source electrode, and a drain electrode. A data pad and a gate pad, both being made of the same material and process, are located coplanarly within the pad region, wherein the gate pad is electrically connected to the gate electrode, and the data pad is electrically connected to the source electrode.

The active matrix substrate further comprises a gate insulating layer formed on the substrate and between the gate electrode and the semiconductor layer, and covering the gate electrode, part of the gate pad, and part of the data pad. A gate contact hole and a a data contact hole are disposed respectively, on the gate pad and the data pad to expose the gate pad and the data pad respectively. An inorganic passivation layer is formed within the active region to cover the thin film transistor. An organic protection layer is formed on the inorganic passivation layer within the active region. A drain contact hole passes through the organic protection layer and the inorganic passivation layer to expose the drain electrode. A plurality of patterned transparent electrodes are formed on the organic protection layer and the gate insulating layer to contact the gate pad, data pad, and drain electrode respectively through the gate contact hole, the data contact hole and the drain contact hole.

Methods for fabricating the active matrix substrate with UAH pixel structure are also provided, in which a substrate having an active region and a pad region is provided. A gate electrode is formed within the active region. A gate pad and a data pad are of the same material and formed within the pad region by the same process, wherein the gate pad and the data pad are located coplanarly. A gate insulating layer is formed on the substrate so as to cover the gate electrode, part of the gate pad, and part of the data pad. A semiconductor layer, a source electrode, and a drain electrode are formed on the gate insulating layer, to form a thin film transistor.

Some embodiments of a method for fabricating the active matrix substrate may further comprise, after forming the TFT, an inorganic material layer and an organic material layer sequentially formed on the substrate to cover the thin film transistor. A part of the organic material layer is removed to expose the inorganic material layer directly on the drain, the data pad, and the gate pad. The organic material layer, the inorganic material layer and the gate insulating layer are patterned to form an organic protection layer and an inorganic passivation layer within the active region to expose a part of the drain electrode, the gate pad, and the data pad. A plurality of patterned transparent electrodes are formed on the organic protection layer and the gate insulating layer, wherein the plurality of patterned transparent electrodes contact the gate pad, the data pad, and the drain electrode respectively. Particularly, the process of forming the gate electrode, the gate pad and the data pad comprises forming a first metal layer on the substrate, and then patterning the first mask layer to form the gate electrode, the gate pad, and the data pad simultaneously. Furthermore, the process of forming the source electrode and the drain electrode comprises forming a second metal layer over the gate insulating layer, and then patterning the second metal layer to form the source electrode and the drain electrode simultaneously.

A detailed description is given in the following with reference to the accompanying drawings.

### BRIEF DESCRIPTION OF THE DRAWINGS

The invention can be more fully understood by reading the subsequent detailed description in conjunction with the examples and references made to the accompanying drawing, wherein:

FIG. 1 is a top view of a conventional LCD with UHA pixel structure.

FIG. 2 shows sectional diagrams of FIG. 1 along lines A-A′, B-B′, and C-C′.

FIGS. 3 and 4 are cross-sections of conventional LCDs with UHA pixel structure.

FIG. 5 is a top view illustrating pixel structure of an active matrix substrate employed in a flat panel display according to an embodiment of the invention.

FIGS. 6a to 6f are cross-sections of an embodiment of a method for fabricating an active matrix substrate employed in a flat panel display.

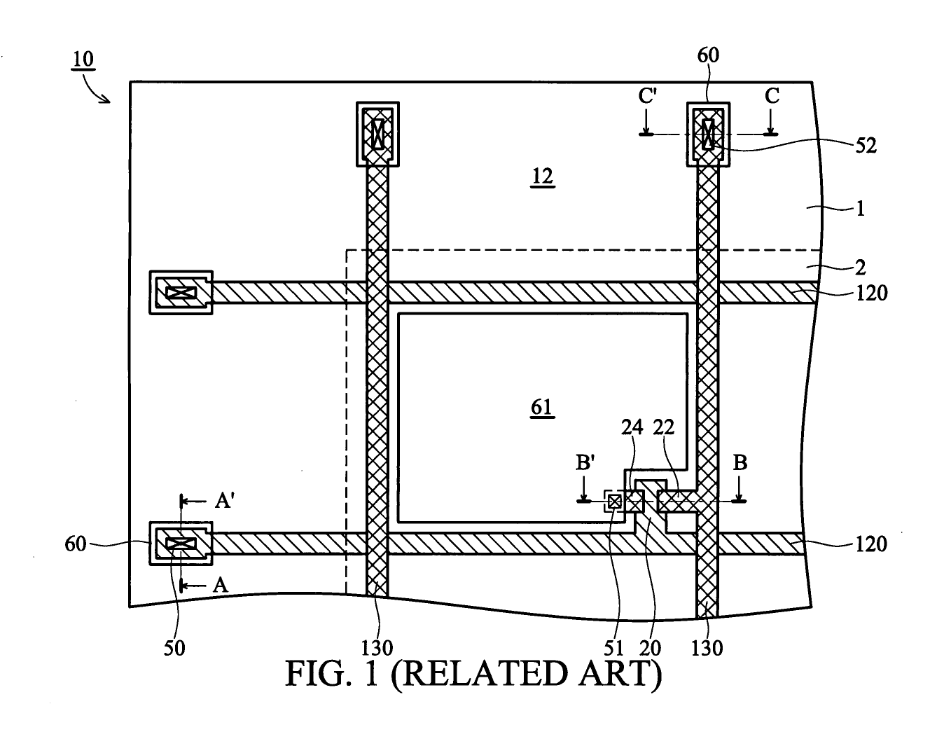

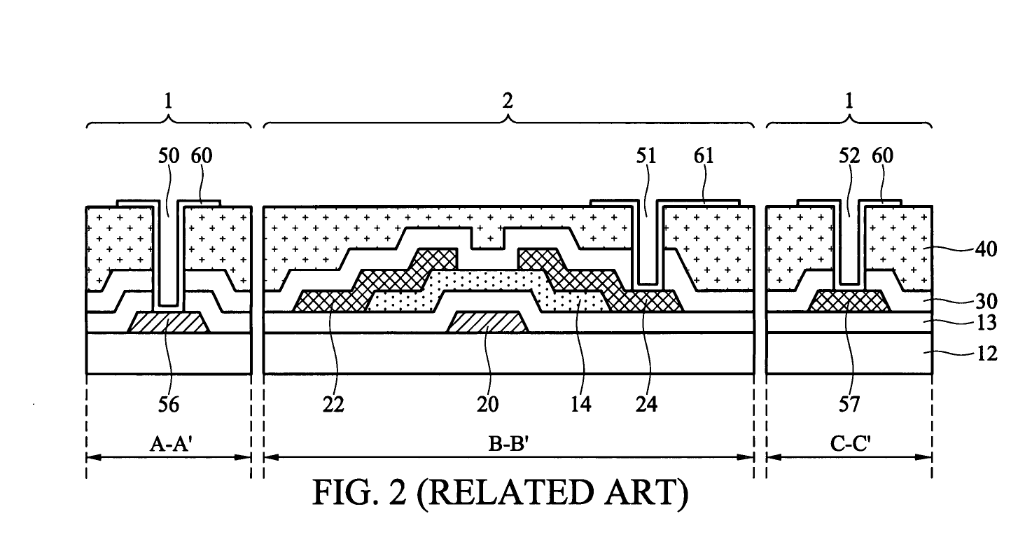

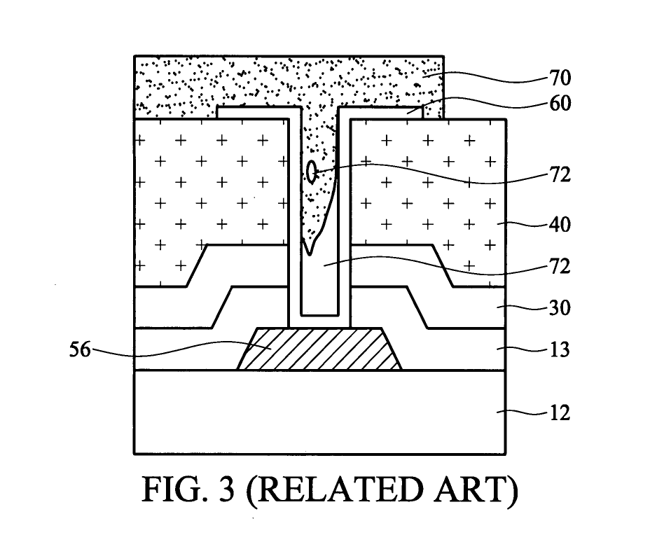

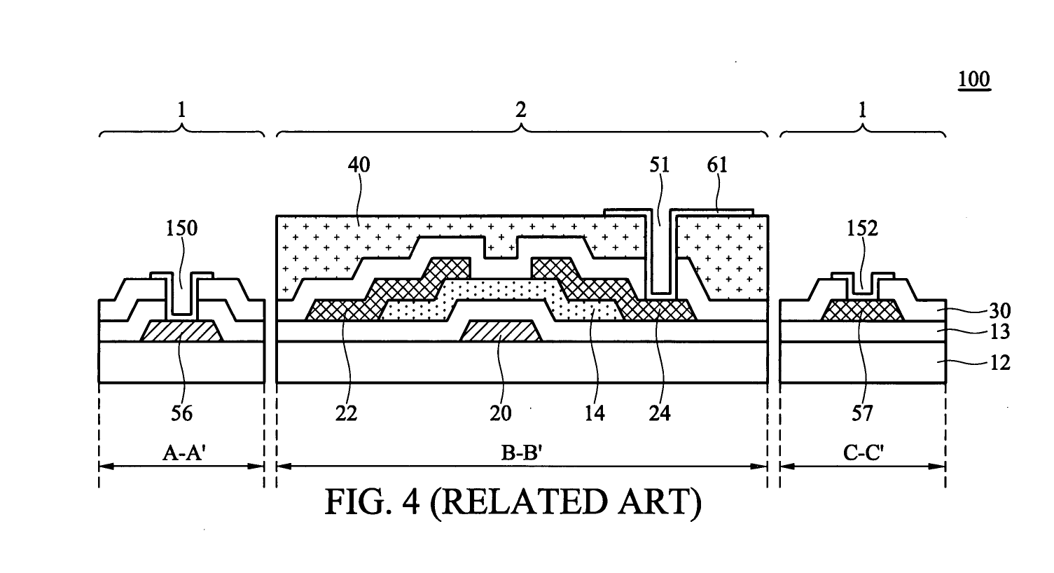

### DETAILED DESCRIPTION

A method of fabricating an active matrix substrate with UAH pixel structure employs only five photolithography steps, thereby reducing the photolithography steps of conventional process and avoiding alignment errors. Furthermore, the gate pad and the data pad are made of the same material and formed coplanarly by the same process.

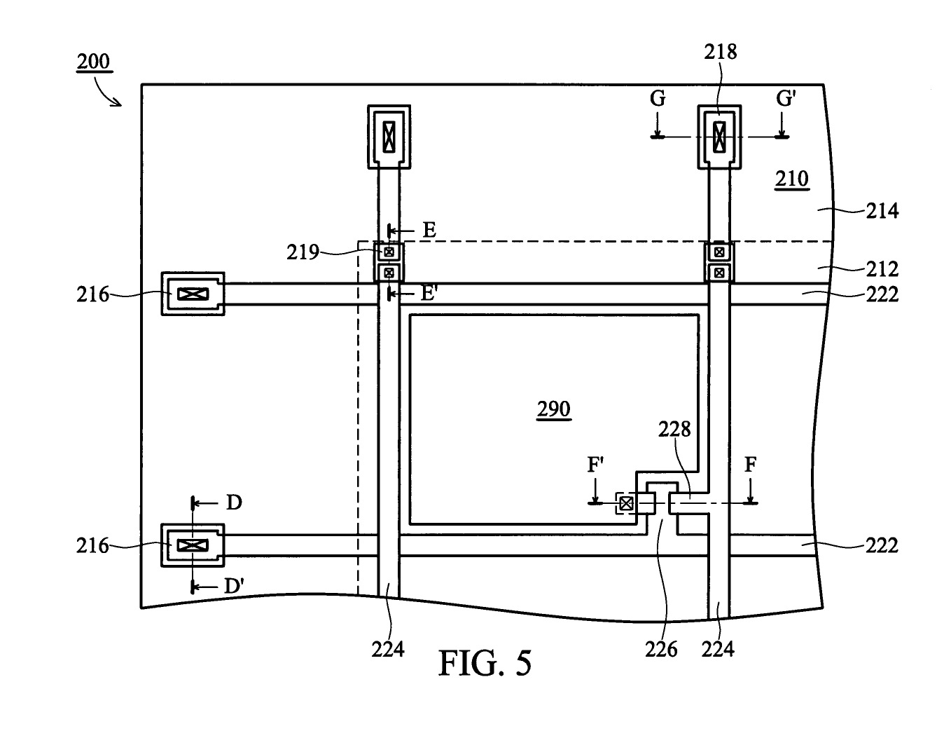

FIG. 5 is a partial topview of an active matrix substrate 200 employed in flat panel display, such as an LCD, according to an embodiment of the invention. The active matrix substrate 200 comprises a substrate 210 which is defined as an active region 212, and a pad region 214. Gate pads 216 and data pads 218 are formed coplanarly in the pad region 214, wherein the gate pads 216 electrically connect to a gate electrode 226 through a gate line 222, and the data pads 218 electrically connect to a source electrode 228 through a data line 224. As a main feature and a key aspect, the gate pads 216 are level with the data pads 218, and the pads 216 and 218 are of the same material and formed by the same process.

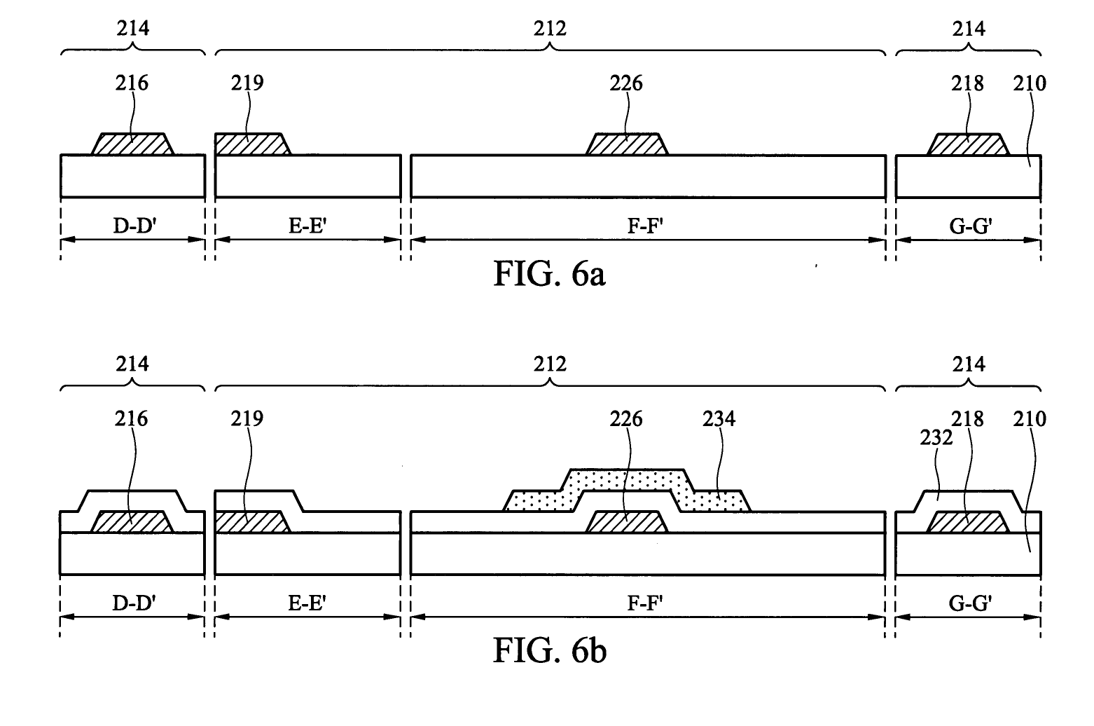

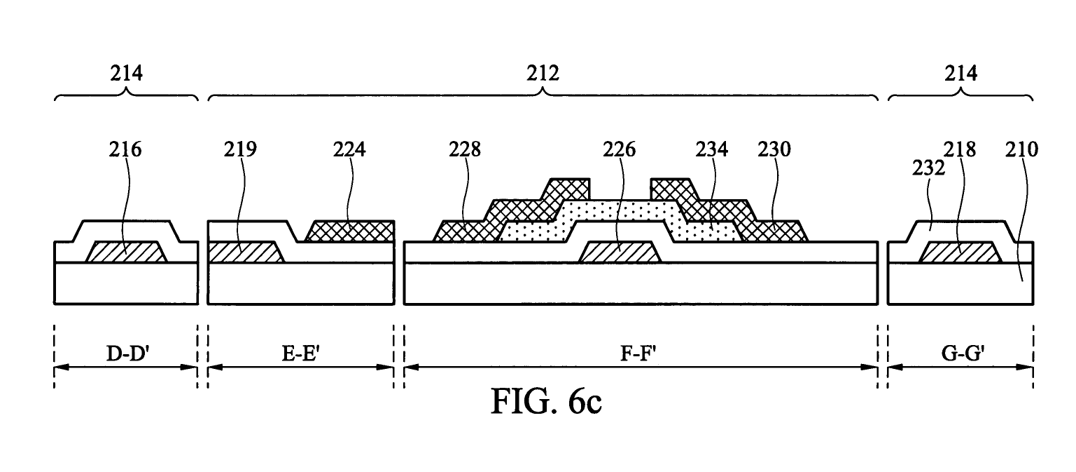

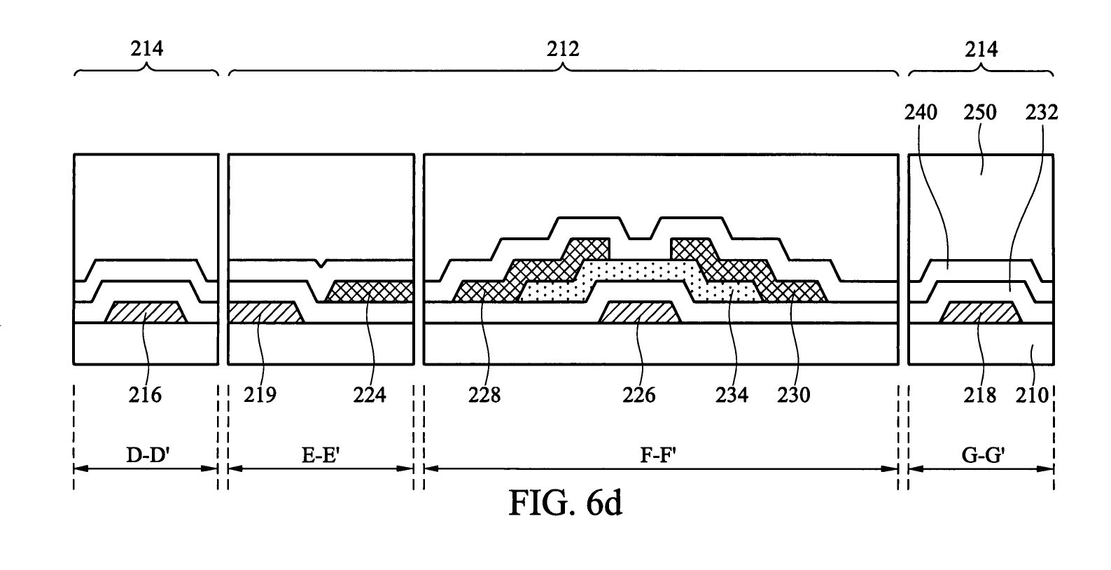

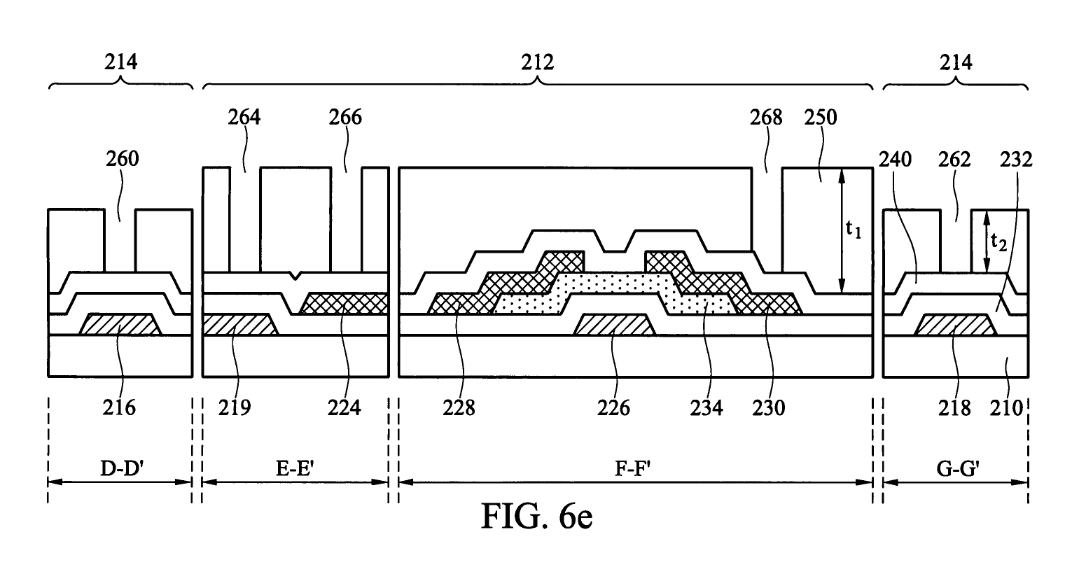

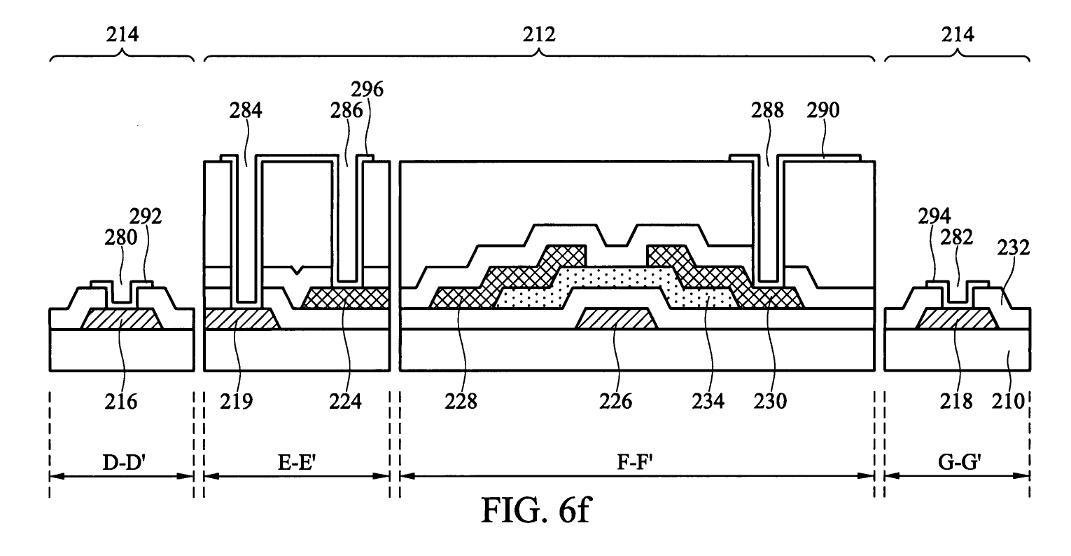

FIGS. 6a to 6f, sectional diagrams of FIG. 5 along lines D-D′, E-E′, F-F′, and G-G′, show the method for fabricating the active matrix substrate 200.

First, a first metal material layer is formed on the substrate 210 and patterned to form a gate electrode 226 in the active region 212, and a gate pad 216 and date pad 218 in the pad region 214 by a first photolithography step. Particularly, the gate electrode 226 electrically connects to the gate pad 216 through the gate line 222, and the data pad has an extending contact region 219 within the active region 212. Namely, the gate pad 216, the date pad 218, and the gate electrode 226 are formed of the first metal and by the same process. Referring to FIG. 6a, it should be noted that the gate pad 216 and the data pad 218 are formed coplanarly on the substrate 210. The first metal material can be Al, Cu, Mo or an alloy thereof.

Next, referring to FIG. 6b, a gate insulating layer 232 is formed on the substrate 210, and a semiconductor layer is formed on the gate insulating layer 232 over the gate electrode 226 by a second photolithography step. The gate insulating layer 232 can be silicon nitride or silicon oxide, 2000˜4000 Å thick. The semiconductor layer comprises a silicon-containing layer, such as polysilicon, single crystal silicon, or amorphous silicon. Take a polysilicon layer as the example, the fabrication method can comprise forming an amorphous silicon layer, and then treating the amorphous silicon layer by thermal application or excimer laser annealing (ELA), having a temperature range of 400° C. to 650° C., to crystallize the amorphous silicon layer through solid or liquid phase growth.

Next, referring to FIG. 6c, a second metal material layer is formed on the substrate 210 and patterned to form a source electrode 228, a drain electrode 230, and a data line 224 within the active region 212 by a third photolithography step, in which the second metal material layer within the pad region 214 is completely removed. The second metal material can be Al, Ti, Ta, Cr, Mo, W or an alloy thereof.

Next, referring to FIG. 6d, an inorganic material layer 240 and an organic material layer 250 are sequentially formed on the above structure. The inorganic material layer 240 can be nitride, oxide, or silicide and 2000˜4000 Å thick. The organic material layer 250 comprises a transparent polymer with low dielectric constant, 30000 Å˜40000 Å thick.

Next, referring to FIG. 6e, the organic material layer 250 is patterned by a fourth photolithography step to form first openings 260 and 262 exposing the inorganic material layer 240 over the gate pad 216 and the data pad 218 respectively, a second opening 264 exposing the inorganic material layer 240 over the extending contact region 219, a third opening 266 exposing the inorganic material layer 240 over the data line 224, and a fourth opening 268 exposing the inorganic material layer 240 over the drain electrode 230.

It should be noted that the remaining organic material layer 250 has different thicknesses, wherein the organic material layer 250 within the active region 212 has a first thickness t1, and the organic material layer 250 within the pad region 214 a second thickness t2. Particularly, the ratio between the first thickness t1 and second thickness t2 is 5:4 to 3:1. Here, the fourth photolithography step can employ a halftone mask, thereby forming the organic material layer 250 with different thickness.

Next, the organic material layer 250, the inorganic material layer 240, and the gate insulating layer 232 are etched with the patterned organic material layer 250 acting as an etching mask. In the etching step, the organic material layer 250 within the pad region 214 is completely removed, and first contact holes 280 and 282 are formed to expose the gate pad 216 and data pad 218, the second contact holes 284 formed to expose the extending contact region 219, the third contact holes 286 formed to expose the data line 224, and the fourth contact holes 288 formed to expose the drain electrode 230.

Next, a transparent conductive layer is formed on the substrate to fill the contact holes. The transparent conductive layer is then patterned by a fifth photolithography step to form a pixel electrode 290 and a conductive layer 296 in the active region 212, and a gate pad contact region 292 and a data pad contact region 294 in the pad region 214. Particularly, the pixel electrode 290 is electrically connected to the drain electrode 230, and the gate pad region and data pad contact region 292 and 294 are connected to the gate pad 216 and the data pad 218, respectively. Further, the connection 296 electrically connects the data line 224 to the data pad 218. The transparent conductive layer comprises indium tin oxide (ITO), indium zinc oxide (IZO), aluminum zinc oxide (AZO), or zinc oxide (ZnO).

Since the organic material layer in the pad region is removed without additional photolithography, yield and throughput are enhanced.

Furthermore, the gate pad is level with the data pad, having the same depth as the data pad contact hole, resulting in an unlimited process window.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. An active matrix substrate for use in a flat panel display, comprising:
a substrate having an active region and a pad region;
a thin film transistor disposed within the active region, comprising a gate electrode, a semiconductor layer, a source electrode, and a drain electrode; and
a gate pad and a data pad, both being made of the same material and located coplanarly within the pad region, wherein the gate pad is electrically connected to the gate electrode, and the data pad is electrically connected to the source electrode

2. The active matrix substrate as claimed in claim 1, further comprising:
a gate insulating layer, disposed on the substrate and between the gate electrode and the semiconductor layer, and covering the gate electrode, part of the gate pad, and part of the data pad;
a gate contact hole and a data contact hole disposed, respectively, on the gate pad and the data pad to expose the gate pad and the data pad;
an inorganic passivation layer, disposed within the active region, formed on the gate insulating layer and covering the thin film transistor;
an organic protection layer, disposed within the active region, formed on the inorganic passivation layer;
a drain contact hole passing through the inorganic passivation layer and the organic protection layer to expose a part of the drain electrode; and
a plurality of patterned transparent electrodes, formed on the organic protection layer and the gate insulating layer, contacting the gate pad, the data pad and the drain electrode, respectively, through the gate contact hole, the data contact hole and the drain contact hole.

3. The active matrix substrate as claimed in claim 1, wherein the gate electrode, the gate pad, and the data pad are made of a first metal.

4. The active matrix substrate as claimed in claim 3, wherein the drain electrode and source electrode are made of a second metal.

5. The active matrix substrate as claimed in claim 4, further comprising a conductive layer electrically connecting the data pad to the source electrode.

6. The active matrix substrate as claimed in claim 5, wherein the conductive layer comprises indium tin oxide.

7. The active matrix substrate as claimed in claim 3, wherein the first metal comprises Al, Cu, Mo, or an alloy thereof.

8. A method for fabricating an active matrix substrate for use in a flat panel display, comprising:
providing a substrate having an active region and a pad region;
forming a gate electrode within the active region;
forming a gate pad and a data pad coplanarly within the pad region, wherein the gate pad and data pad are of the same material;
forming a gate insulating layer on the substrate so as to cover the gate electrode, part of the gate pad, and part of the data pad; and
forming a semiconductor layer, a source electrode, and a drain electrode on the gate insulating layer to form a thin film transistor.

9. The method as claimed in claim 8, further comprising:
forming an inorganic material layer on the gate insulating layer so as to cover the thin film transistor;
forming an organic material layer on the inorganic material layer;
removing selectively the organic material layer to expose a part of the inorganic material layer on the drain, the data pad, and the gate pad;
patterning the organic material layer, the inorganic material layer and the gate insulating layer to form an organic protection layer and an inorganic passivation layer within the active region and to expose a part of the drain electrode, the gate pad, and the data pad; and
forming a plurality of patterned transparent electrodes on the organic protection layer and the gate insulating layer, wherein the plurality of patterned transparent electrodes contact the drain electrode, the gate pad, and the data pad, respectively.

10. The method as claimed in claim 9, wherein, in the patterning step, a gate contact hole, a data contact hole and a drain contact hole are formed.

11. The method as claimed in claim 9, wherein, in the patterning step, the organic material layer and the inorganic material layer formed within the pad region are completely removed.

12. The method as claimed in claim 8, wherein forming the gate electrode, the gate pad and the data pad comprises:
forming a first metal layer on the substrate; and
patterning the first metal layer to form the gate electrode, the gate pad, and the data pad.

13. The method as claimed in claim 12, wherein forming the source electrode and the drain electrode comprises:
forming a second metal layer over the gate insulating layer; and
patterning the second metal layer to form the source electrode and the drain electrode.

14. The method as claimed in claim 13, wherein, in the step of patterning the second metal layer, the second metal layer formed within the pad region is completely removed.

15. The method as claimed in claim 13, further comprising forming a conductive layer connecting the data pad to the patterned second metal layer.

16. The method as claimed in claim 15, wherein the conductive layer and the patterned transparent electrodes are of the same material and formed by the same process.

17. The method as claimed in claim 12, wherein the first metal material comprises Al, Cu, Mo, or an alloy thereof.
